(19) United States
(12) Patent Application Publication
(10) Pub. No.: US 2026/0105683 A1
(43) Pub. Date: Apr. 16, 2026

(54) METHOD AND DEVICE FOR CALIBRATING VEHICLE, AND COMPUTER STORAGE MEDIUM EMPLOYING METHOD

(71) Applicant: HON HAI PRECISION INDUSTRY CO., LTD., New Taipei (TW)

(72) Inventors: CHUN-ZHUANG MIAO, New Taipei (TW); Chih-Chieh Sun, New Taipei (TW); Jun-Yu Chuang, New Taipei (TW)

(21) Appl. No.: 18/941,293

(22) Filed: Nov. 8, 2024

(30) Foreign Application Priority Data
Oct. 10, 2024 (CN) 202411410482.8

(51) Int. Cl. G06T 17/00

(52) U.S. Cl. CPC G06T 17/00

(57) ABSTRACT

A vehicle calibrating method for calibrating vehicle based on a virtual reality technology includes: displaying a predetermined driving scene to a user corresponding to an objective vehicle device in a preset virtual reality environment, the predetermined driving scene being generated by a virtual simulation of a real calibration scene corresponding to the objective vehicle device; collecting device parameters of the objective vehicle device when receiving operation information of the objective vehicle device inputted by the user; performing a simulation calculation to obtain predicted performance data of the objective vehicle device according to the operation information, the device parameters, and scene parameters of the predetermined driving scene; and displaying the predicted performance data to the user for calibrating the objective vehicle device. A vehicle calibrating device and a non-transitory storage medium are also provided.

### TECHNICAL FIELD

The subject matter herein generally relates to vehicle calibration technologies.

### BACKGROUND

Vehicle calibration plays an important role in a vehicle development. The vehicle calibration refers to a process of optimizing vehicle performance, and ensuring vehicle reliability and safety by adjusting vehicle control parameters. However, the vehicle calibration is a complex process, and current calibration process include a large number of physical tests, and most of the physical tests are performed in extreme test environments, which is time-consuming, high risky, and high cost.

Therefore, there is a need of providing an improved vehicle calibration method.

### BRIEF DESCRIPTION OF THE DRAWINGS

Implementations of the present disclosure will now be described, by way of embodiments, with reference to the attached figures.

FIG. 1 is a flowchart illustrating a vehicle calibrating method according to an embodiment of the present disclosure.

FIG. 2 is a sub-flowchart of the vehicle calibration method shown in FIG. 1.

FIG. 3 is another sub-flowchart of the vehicle calibration method shown in FIG. 1.

FIG. 4 is another sub-flowchart of the vehicle calibration method shown in FIG. 1.

FIG. 5 is a flowchart illustrating a vehicle calibrating method according to another embodiment of the present disclosure.

FIG. 6 is a sub-flowchart of the vehicle calibration method shown in FIG. 5.

FIG. 7 is a block diagram illustrating a vehicle calibrating device according to an embodiment of the present disclosure.

FIG. 8 is a block diagram illustrating an electronic device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. It should be noted that references to “an” or “one” embodiment in this disclosure are not necessarily to the same embodiment, and such references mean “at least one”.

Several definitions that apply throughout this disclosure will now be presented.

The term “coupled” is defined as connected, whether directly or indirectly through intervening components, and is not necessarily limited to physical connections. The connection can be such that the objects are permanently connected or releasable connected. The term “comprising,” when utilized, means “including, but not necessarily limited to”; it specifically indicates open-ended inclusion or membership in the so-described combination, group, series, and the like.

Vehicle calibration refers to a process of optimizing vehicle performance and ensuring vehicle reliability, vehicle safety, environmental protection, etc., by adjusting vehicle control parameters. With a updating of environmental regulations and a upgrading of user driving experience requirements, the vehicle calibration is becoming more frequent and complex. In order to ensure an effect of the vehicle calibrations, the vehicle calibration is generally performed in relatively extreme environments and/or diverse environments. As a result, the vehicle calibration requires vehicle calibration personnel to be in various environments, whose personal safety cannot be guaranteed, and a cost of the vehicle calibration is high, which also affects an efficiency of the vehicle calibration and takes a long time for vehicle calibration.

One way of vehicle calibration based on a remote control technology may generally apply to specific vehicle components and specific calibration requirements, which also has problems of limited applicable demand scenes and poor real-time. An efficiency of vehicle calibration and an availability of a calibration result based on the remote control technology are also poor.

In view of this, one embodiment of the present application provides a vehicle calibration method to achieve safer, efficient and accurate vehicle calibration.

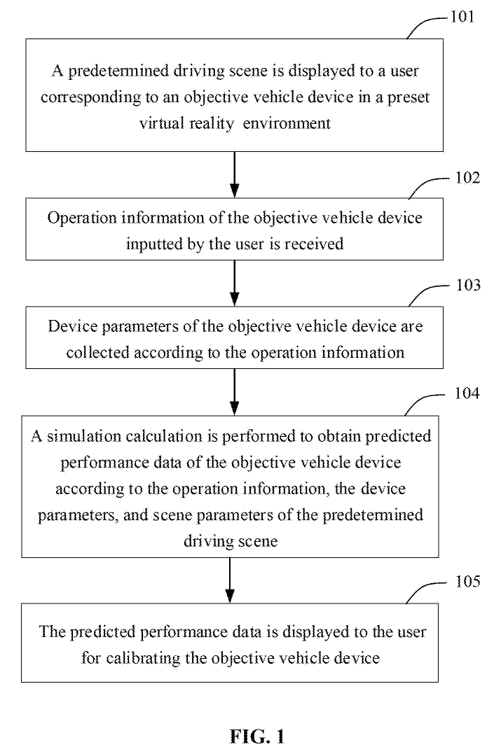

FIG. 1 illustrates one exemplary embodiment of the vehicle calibration method. The method can be applied to a vehicle calibration device. The vehicle calibration device can be a computer, a server, etc. The flowchart presents an exemplary embodiment of the method. The exemplary method is provided by way of example, as there are a variety of ways to carry out the method. Each block shown in FIG. 1 may represent one or more processes, methods, or subroutines, carried out in the example method. Furthermore, the illustrated order of blocks is illustrative only and the order of the blocks can change. Additional blocks can be added or fewer blocks may be utilized, without departing from this disclosure. The example method can be begin at block 101.

In block 101, a predetermined driving scene is displayed to a user corresponding to an objective vehicle device (a vehicle device to be calibrated) in a preset virtual reality (VR) environment.

In one embodiment, the predetermined driving scene can be generated by a virtual simulation of a real calibration scene corresponding to the objective vehicle device.

In one embodiment, the objective vehicle device can include specific vehicle components and specific vehicle systems of an objective vehicle, or the objective vehicle device can be the objective vehicle. The specific vehicle components and the specific vehicle systems can be components and systems that are critical to vehicle performance.

In one embodiment, the specific vehicle components may include an engine, a motor, etc. The specific vehicle systems may include a power system, a battery management system, a suspension system, a chassis system, an automatic driving system, a vehicle control system, a braking system, a steering system, a safety system, etc.

In one embodiment, the user corresponding to the objective vehicle device can be a user who wants to calibrate the objective vehicle device. For example, the user corresponding to the objective vehicle device can be a vehicle calibration personnel. Comparing the current vehicle calibration, the objective vehicle device and the vehicle calibration personnel are required to be placed in a real calibration environment that may be complex and/or extreme. In this embodiment, the predetermined driving scene display to the user is generated by simulating according to the real calibration scene. By controlling the objective vehicle device and interacting with the predetermined driving scene in the VR environment, the user can obtain a vehicle calibration experience close to the real calibration scene.

In one embodiment, the real calibration scene refers to a reality environment when the objective vehicle device is calibrated in a reality scene. The predetermined driving scene may simulate that the objective vehicle device and the vehicle calibration personnel are in the reality environment. For example, the real calibration scene can include driving environments actually existing in the real world, such as high temperature environments, high cold environments, plateau environments, desert environments, wetland environments, etc.

By collecting road parameters and environmental parameters of the real calibration scene, the road parameters and the environmental parameters of the real calibration scene can be processed to display the predetermined driving scene in the VR environment according to a preset three-dimensional (3D) modeling technology and a stereoscopic display technology.

In one embodiment, the road parameters can include road slope, road width, road wetness, etc. The environmental parameters can include temperature, humidity, visibility, air pressure, altitude, etc. The 3D modeling technology can include 3D scanning technology, light field capture technology, etc. The stereoscopic display technology can include holographic projection technology, light field imaging technology, etc.

In order to provide a better calibration experience and simulate calibrating the objective vehicle device in the real calibration scene, a display location of the predetermined driving scene can be set according to a location of the user and/or a location of the objective vehicle device. For example, the predetermined driving scene is displayed in front of the objective vehicle device, to simulate a drive experience in a real calibration process.

Exemplary, on a basis of road and environment simulation, in order to provide a more realistic calibration experience for the user, the predetermined driving scene may simulate an operation interface corresponding to the objective vehicle device, and the user can input operation parameters through the operation interface.

In one embodiment, a performance of device or components displayed in the VR environment is preset to meet an ideal condition, no calibration is required, and device or components that need to be calibrated can be real and can be operated by the user.

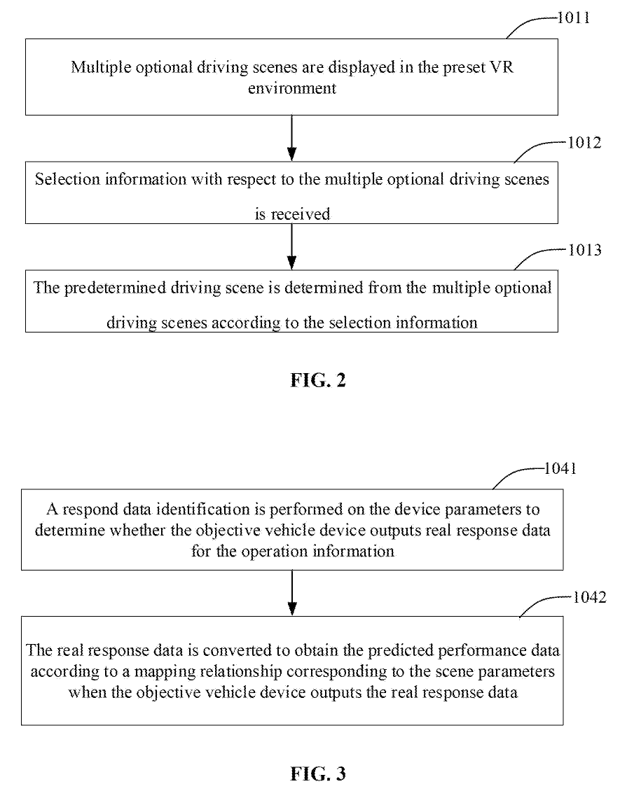

Optionally, in order to test the performance of the objective vehicle device under various environments and various test requirements for fully calibrating the objective vehicle device, as shown in FIG. 2, block 101 may further include block 1011, block 1012, and block 1013.

In block 1011, multiple optional driving scenes are displayed in the preset VR environment.

In one embodiment, the multiple optional driving scenes can be generated by a virtual simulation on multiple optional real calibration scenes.

In one embodiment, the multiple optional real calibration scenes can correspond to different environmental and/or different road parameters to represent various environments in which the objective vehicle device and/or the users may need to be located during vehicle calibration. It is understandable that in reality, calibration information of vehicle devices under specific scenes and specific user based on calibration operations need to be collected, and a realization of vehicle calibration in the specific scenes requires high costs, such as high construction costs and high transportation costs, etc. In this embodiment, in order to meet various calibration needs of the user/the objective vehicle device, multiple optional driving scenes are displayed in the VR environment for the user to select, to achieve personalized, efficient and safe vehicle calibration.

In block 1012, selection information with respect to the multiple optional driving scenes is received.

In one embodiment, the user can input the selection information through preset VR interactive devices, for example, the user can select the predetermined driving scene from the multiple driving scenes displayed in the preset VR environment by virtual reality joysticks, headcovers, glasses, or other interactive devices. The selection information can include identification information of an optional driving scene selected by the user.

In block 1013, the predetermined driving scene is determined from the multiple optional driving scenes according to the selection information.

In one embodiment, the selection information can be parsed to obtain the identification information, and the predetermined driving scene selected by the user is obtained according to the identification information of the optional driving scene selected by the user.

In block 102, operation information of the objective vehicle device inputted by the user is received.

In one embodiment, information of operation instructions (operation information) of the objective vehicle device inputted by the user can be detected. The operation instructions can be configured to adjust parameters of the objective vehicle device and/or control the objective vehicle device. Controlling the objective vehicle device may include: testing functions of the objective vehicle device.

Considering that in the real vehicle calibration process, with an adjustment of vehicle parameters and a change of functional test operation, the vehicle may respond to different response data in different driving scenes. The user can adjust a calibration strategy in real time according to the response data experienced by the user and a calibration experience of the user, so as to improve an accuracy of vehicle calibration. In order to improve a simulation degree of vehicle calibration based on the predetermined driving scene displayed in the VR environment, after receiving the operation information, some embodiments may further include: dynamically adjusting the predetermined driving scene in the preset VR environment according to the operation information.

In one embodiment, a preset VR interaction technology and a simulated driving technology can be used to simulate a impact of the objective vehicle device on a real environment after responding to the operation information of the user in the predetermined driving scene. For example, when the operation information indicates a braking operation, brake marks on the road can be simulated in the predetermined driving scene according to braking parameters of the braking operation. When the operation information indicates that the user drives the vehicle forward, roads and sceneries displayed in front of the user can be adjusted in a follow manner. Optionally, interactive devices used by the user can be controlled to simulate an auditory and/or a tactile experience based on an adjustment of the predetermined driving scene, such as when the user drives the vehicle to accelerate, an operation sound of the engine and a poke experience of the seat can be simulated.

In block 103, device parameters of the objective vehicle device are collected according to the operation information.

In one embodiment, the device parameters may include fixed parameters and non-fixed parameters of the objective vehicle device. The non-fixed parameters can be changed according to the operation information of the objective vehicle device inputted by the user. A change of a non-fixed parameter can be directly changed by a calibration operation on the non-fixed parameter, or can be indirectly changed with a calibration operation on other non-fixed parameters.

In one embodiment, the user can optimize a performance of the objective vehicle device by adjusting calibrable parameters to meet calibration requirements of the vehicle. For example, the calibrable parameters can include speed, acceleration, gear, temperature, delay rate, error rate, etc. The fixed parameters generally cannot be calibrated and adjusted by the user. For example, the fixed parameters can be preset core system parameters or identification parameters for indicating a device type of the objective vehicle device.

In one embodiment, the fixed parameters can include vehicle type information, controller protocol, etc.

In block 104, a simulation calculation is performed to obtain predicted performance data of the objective vehicle device according to the operation information, the device parameters, and scene parameters of the predetermined driving scene.

In one embodiment, common links of vehicle calibration in VR environment and vehicle calibration in real environment include real operations of the objective vehicle device inputted by the user, such as real calibration operations, real test operations, etc. The difference is that the vehicle calibration in the real environment can directly collect real vehicle response data and real driving environment parameters. The objective vehicle device in this embodiment does not operate in the real calibration scene. Therefore, a simulation calculation is performed based on the operation information, the device parameters, and scene parameters of the predetermined driving scene, and the predicted performance data of the objective vehicle device can be obtained, providing a basis and a reference for vehicle calibration.

In one embodiment, an expected performance of the objective vehicle device under an ideal condition can be determined based on the operational information, and the expected performance can be adjusted based on the environmental parameters and device parameters to obtain the predicted performance data. For example, the predicted performance data may include acceleration performance, braking performance, durability performance, operational stability of the objective vehicle device.

Referring to FIG. 3, block 104 may include block 1041 and block 1042.

In block 1041, a respond data identification is performed on the device parameters to determine whether the objective vehicle device outputs real response data with respect to the operation information.

In one embodiment, part of vehicle calibration can be performed based on an output monitoring of corresponding vehicle components to achieve parameter calibration of the corresponding vehicle components. For example, calibrating battery health, battery durability, charge and discharge performance can be performed based on an output monitoring of a vehicle battery.

In one embodiment, the predicted performance data of the objective vehicle device can be obtain based on the real response data of the objective vehicle device and an expected performance impact of the predetermined driving scene.

In one embodiment, the respond data identification can be performed on the device parameters to determine that the real response data is detected from the objective vehicle device.

In block 1042, the real response data is converted to obtain the predicted performance data according to a mapping relationship corresponding to the scene parameters when the objective vehicle device outputs the real response data.

In one embodiment, the mapping relationship can be configured to indicate a mapping between the real response data and a performance of the objective vehicle device.

In one embodiment, the objective vehicle device responds to the operation information in an environment where the user is located, not necessarily in a real objective calibration scene. Therefore, the real response data output by the objective vehicle device may be not affected by environmental factors in the real objective calibration scene. In order to improve a simulation degree of the predicted performance data, the real response data can be converted to obtain the predicted performance data according to the mapping relationship corresponding to the scene parameters.

In one embodiment, the mapping relationship can be determined based on historical calibration experience data corresponding to the real objective calibration scene, or can be determined by combining a big data technology and/or an artificial intelligence technology.

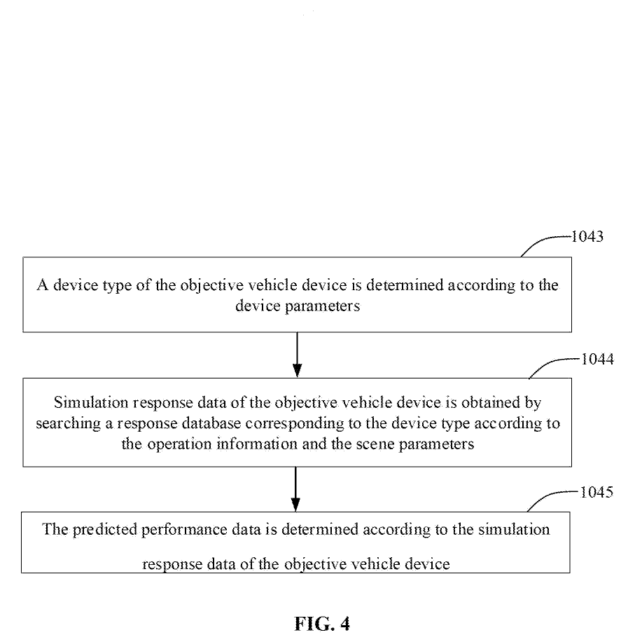

Referring to FIG. 4, block 104 may include block 1043, block 1044, and block 1045.

In block 1043, a device type of the objective vehicle device is determined according to the device parameters.

In one embodiment, the device type can be used to indicate otherness characteristic of the objective vehicle device, including but not limited to function type, hardware feature type, software feature type, etc. For example, the function type may indicate a function of the objective vehicle device in a vehicle driving, such as power, battery, automatic driving, suspension, etc. The hardware type may include a hardware structure type and a manufacturer type of the objective vehicle device, and the software type may include a software system type and a communication protocol type of the objective vehicle device.

In block 1044, simulation response data of the objective vehicle device is obtained by searching a response database corresponding to the device type according to the operation information and the scene parameters.

In one embodiment, the response database may include a plurality of simulation response data of the objective vehicle device corresponding to multiple optional operations in multiple optional scenes. The response database can be established according to at least one of historical calibration data of the objective vehicle equipment, a big data technology and, an artificial intelligence inference technology.

In one embodiment, a influence of the device type may be existed on a response of the objective vehicle device in different operations and/or different environments. The simulation response data corresponding to the operation information inputted by the user and the scene parameters on the objective vehicle device of the current device type is simulated based on a pre-built response database. Therefore, without collecting the real response data of the objective vehicle device, the response data of the objective vehicle device can also be predicted, providing a reliable basis for vehicle calibration in following steps.

In block 1045, the predicted performance data is determined according to the simulation response data of the objective vehicle device.

In one embodiment, response data of the vehicle to various operations can characterize performances of the vehicle in some aspect, such as a response of a battery system to a charge and discharge operation can represent a health performance of the battery system, etc. Therefore, the simulation response data can be converted according to a preset conversion relationship between the response data and the performance data, to obtain the predicted performance data.

In block 105, the predicted performance data is displayed to the user for calibrating the objective vehicle device.

After displaying the predicted performance data, the user can intuitively notice the predicted performance data and calibrate the objective vehicle device according to the predicted performance data.

By displaying the predetermined driving scene in the VR environment according to the real calibration scene, the user does not need to spend high cost to go to real complex and dangerous calibration environments when calibrating the objective vehicle device, and a simulation visual experience similar to being in the real calibration scene can be provided to the user. A calibration atmosphere and a calibration result reference for calibrating vehicle devices can be provided to the user, improving a vehicle calibration experience of the user. In addition, the predicted performance data of the objective vehicle device is obtained by inference simulation according to the operation information, the current device parameters of the objective vehicle device, and the scene parameters of the predetermined driving scene. The predicted performance data can be used to simulate performance data that can be collected after the user operates the objective vehicle device in the real calibration scene. It can provide a basis for the user to perform vehicle calibration, and improve an efficiency and an accuracy of vehicle calibration.

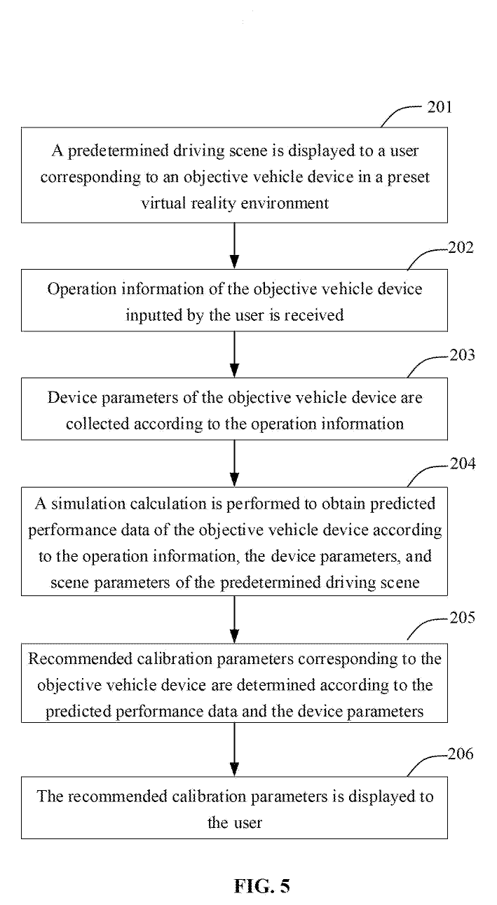

In one embodiment, vehicle calibration exists requirements on calibration experience and calibration ability of users, and manual parameter adjustment is time-consuming and may cause errors or poor effects of calibration operation. In order to improve the efficiency and the accuracy of vehicle calibration, FIG. 5 shows a vehicle calibration method according to another embodiment of the present application.

Referring to FIG. 5, the flowchart presents an exemplary embodiment of the vehicle calibration method. The exemplary method is provided by way of example, as there are a variety of ways to carry out the method. Each block shown in FIG. 5 may represent one or more processes, methods, or subroutines, carried out in the example method. Furthermore, the illustrated order of blocks is illustrative only and the order of the blocks can change. Additional blocks can be added or fewer blocks may be utilized, without departing from this disclosure. The example method can be begin at block 201.

In block 201, a predetermined driving scene is displayed to a user corresponding to an objective vehicle device in a preset virtual reality (VR) environment.

In one embodiment, block 201 of this embodiment is similar to block 101 of the previous embodiment, and is not be repeated here in order to avoid repetition.

In block 202, operation information of the objective vehicle device inputted by the user is received.

In one embodiment, block 202 of this embodiment is similar to block 102 of the previous embodiment, and is not be repeated here in order to avoid repetition.

In block 203, device parameters of the objective vehicle device are collected according to the operation information.

In one embodiment, block 203 of this embodiment is similar to block 103 of the previous embodiment, and is not be repeated here in order to avoid repetition.

In block 204, a simulation calculation is performed to obtain predicted performance data of the objective vehicle device according to the operation information, the device parameters, and scene parameters of the predetermined driving scene.

In one embodiment, block 204 of this embodiment is similar to block 104 of the previous embodiment, and is not be repeated here in order to avoid repetition.

In block 205, recommended calibration parameters corresponding to the objective vehicle device are determined according to the predicted performance data and the device parameters.

Considering the previous vehicle calibration, the calibration strategy needs to be obtained by a vehicle calibration personnel manually analyzing the predicted performance data, which requires a large workload and high requirements on an analysis ability of the vehicle calibration personnel, and a calibration effect cannot be guaranteed. In order to improve the efficiency and the accuracy of vehicle calibration, the predicted performance data can be automatically analyzed by a calibration device, the device parameters can be adjusted based on performance analysis results, and the recommended calibration parameters are obtained to provide a calibration reference for the vehicle calibration personnel.

In one embodiment, the performance analysis results can be analysis results that indicate a prediction of the recommended calibration parameters based on historical calibration data, big data technologies and/or artificial intelligence analysis, or other current calibration knowledge.

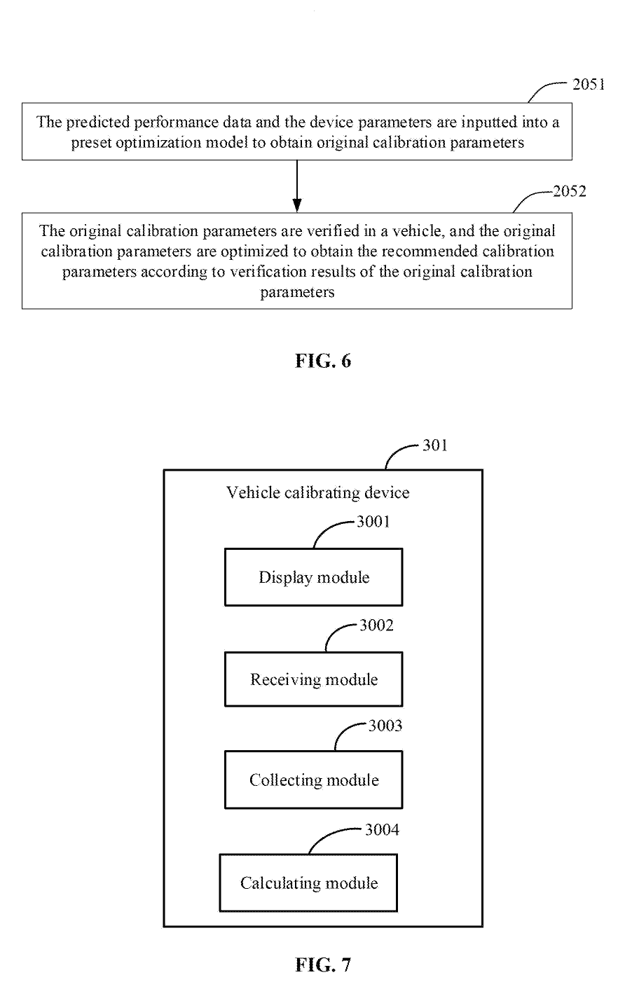

Referring to FIG. 6, block 205 may include block 2051 and block 2052.

In block 2051, the predicted performance data and the device parameters are inputted into a preset optimization model to obtain original calibration parameters.

In one embodiment, the preset optimization model can be trained according to preset multiple calibration parameter samples corresponding to the device parameters and a performance label corresponding to each of the multiple calibration parameter samples.

In one embodiment, the performance label can be used to indicate a performance characteristic that can be obtained after a calibration of the calibration parameter sample on a device corresponding to the device parameters. The device parameters can be used as an analysis basis for predicting performance data. On the one hand, parameter calibration may often need to be adjusted on a basis of the device parameters. On the other hand, different device parameters may represent different device usage states, and the device usage states have an impact on an analysis strategy for predicting performance data. The device usage states can represent specific types of devices and/or states of specific devices, such as a state of a vehicle during a specific gear.

The performance labels corresponding to the calibration parameter samples can be determined according to the historical calibration data, and/or an experience of the vehicle calibration personnel.

In one embodiment, the original calibration parameters can be obtained by analyzing the predicted performance data and the device parameters based on a big data technology and/or an artificial intelligence technology.

In block 2052, the original calibration parameters are verified in a vehicle, and the original calibration parameters are optimized to obtain the recommended calibration parameters according to verification results of the original calibration parameters.

In order to improve an availability and a safety of the original calibration parameters, the original calibration parameters can be applied to the vehicle (real vehicle) corresponding to the objective vehicle device for functional verification, real performance data of the vehicle can be collected. The real performance data is closer to preset performance conditions as a goal, the original calibration parameters are iteratively optimized, to obtain the recommended calibration parameters.

In block 206, the recommended calibration parameters is displayed to the user.

Considering that the vehicle calibration is a task requiring high professional knowledge and having complex work content, the vehicle calibration personnel may have a rich calibration experience and background knowledge on vehicle parameter adjustment. After obtaining the predicted performance data, this embodiment further recommends the calibration parameters based on the predicted performance data, to provide a calibration reference for the vehicle calibration personnel, a workload of vehicle calibration can be greatly reduced and the efficiency of vehicle calibration can be improved.

Referring to FIG. 7, a vehicle calibrating device 301 may include a display module 3001, a receiving module 3002, a collecting module 3003, and a calculating module 3004. Each module may include one or more software programs in a form of computerized codes stored in a data storage. The computerized codes can include instructions that can be executed by a processor to implement the following function of each module. It can be understood that each module may also be a program instruction or a firmware solidified in the processor.

The display module 3001 is configured to display a predetermined driving scene corresponding to an objective vehicle device in a preset VR environment. The predetermined driving scene may be generated by a virtual simulation of a real calibration scene corresponding to the objective vehicle device.

The receiving module 3002 is configured to receive operation information of the objective vehicle device inputted by the user.

The collecting module 3003 is configured to collect device parameters of the objective vehicle device according to the operation information.

The calculating module 3004 is configured to performing a simulation calculation to obtain predicted performance data of the objective vehicle device according to the operation information, the device parameters, and scene parameters of the predetermined driving scene.

The display module 3001 is further configured to display the predicted performance data to the user for calibrating the objective vehicle device.

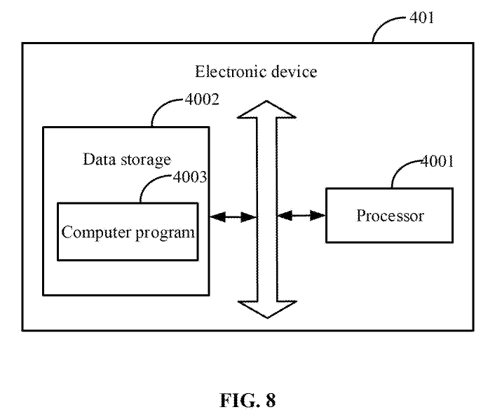

Referring to FIG. 8, an electronic device 401 may include at least one processor 4001, at least one data storage 4002, and a computer program 4003 that is stored in the data storage 4002 and can be run on the processor 4001. When the processor 4001 executes the computer program 4003, the vehicle calibrating method can be realized in the electronic device 401, such as block 101 to block 105 shown in FIG. 1, block 201 to block 206 shown in FIG. 5 can be executed.

For example, when the processor 4001 executes the computer program 4003, the processor 4001 is caused to: display a predetermined driving scene corresponding to an objective vehicle device in a preset virtual reality environment; collect device parameters of the objective vehicle device in response to operation information of the objective vehicle device being received; perform a simulation calculation to obtain predicted performance data of the objective vehicle device according to the operation information, the device parameters, and scene parameters of the predetermined driving scene; and output the predicted performance data for calibrating the objective vehicle device.

In one embodiment, the computer program 4003 be divided into one or more modules/units, and the one or more modules/units are stored in the data storage 4002 and executed by processor 4001. The module or units may be a series of computer instruction segments capable for completing a specific function, and the instruction segments are used for describing a execution process of the computer program 4003 in the electronic device 401.

In one embodiments, the electronic device 401 can be a computer, a server, etc.

In one embodiments, comparing with FIG. 8, the electronic device 401 can include more or less elements, for example, the electronic device 401 can further include input/output devices, network access devices, buses elements, etc.

In one embodiment, the processor 4001 can be a central processing unit (CPU), a microprocessor, a digital signal processors (DSP), an application specific integrated circuit (ASIC), a field-programmable gate array (FPGA), or other data processor chip that achieves the required functions.

The data storage 4002 can be used to store computer programs 40 and/or modules/units, and the processor 4001 can realize various functions of the electronic device 401 by running or executing computer programs and/or modules/units stored in the data storage 4002 and calling up data stored in the data storage 4002. The data storage 4002 can be set in the electronic device 401, or can be a separate external memory card, such as an SM card (Smart Media Card), an SD card (Secure Digital Card), or the like. The data storage 4002 can include various types of non-transitory computer-readable storage mediums. For example, the data storage 4002 can be an internal storage system, such as a flash memory, a random access memory (RAM) for the temporary storage of information, and/or a read-only memory (ROM) for permanent storage of information. The data storage 4002 can also be an external storage system, such as a hard disk, a storage card, or a data storage medium.

The embodiment also provides a non-transitory storage medium, the non-transitory storage medium is configured to store computer instructions, and when the computer instructions are run on the electronic device 401, causes the electronic device 401 to perform the above-mentioned vehicle calibrating method. The non-transitory storage medium can be a ROM, a hard disk, a storage card, etc.

The embodiment also provides a computer program product, and when the computer program product is running on a processor, the processor is caused to perform the above-mentioned vehicle calibrating method.

The embodiments shown and described above are only examples. Many details known in the field are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A vehicle calibrating method comprising:
displaying a predetermined driving scene to a user corresponding to an objective vehicle device in a preset virtual reality (VR) environment, wherein the predetermined driving scene is generated by a virtual simulation of a real calibration scene corresponding to the objective vehicle device;
collecting device parameters of the objective vehicle device when receiving operation information of the objective vehicle device inputted by the user;
performing a simulation calculation to obtain predicted performance data of the objective vehicle device according to the operation information, the device parameters, and scene parameters of the predetermined driving scene; and
displaying the predicted performance data to the user for calibrating the objective vehicle device.

2. The vehicle calibrating method of claim 1, wherein performing the simulation calculation to obtain the predicted performance data of the objective vehicle device according to the operation information, the device parameters, and the scene parameters of the predetermined driving scene comprises:
performing a respond data identification on the device parameters to determine whether the objective vehicle device outputs real response data with respect to the operation information; and
converting the real response data to obtain the predicted performance data according to a mapping relationship corresponding to the scene parameters when the objective vehicle device outputs the real response data;
wherein the mapping relationship is configured to indicate a mapping between the real response data and a performance of the objective vehicle device.

3. The vehicle calibrating method of claim 1, wherein performing the simulation calculation to obtain the predicted performance data of the objective vehicle device according to the operation information, the device parameters, and the scene parameters of the predetermined driving scene comprises:
determining a device type of the objective vehicle device according to the device parameters;
obtaining simulation response data of the objective vehicle device by searching a response database corresponding to the device type according to the operation information and the scene parameters, wherein the response database comprises a plurality of simulation response data of the objective vehicle device corresponding to multiple optional operations in multiple optional scenes, and the response database is established according to at least one of historical calibration data of the objective vehicle equipment, a big data technology and, an artificial intelligence (AI) inference technology; and
determining the predicted performance data according to the simulation response data of the objective vehicle device.

4. The vehicle calibrating method of claim 1, further comprising:
determining recommended calibration parameters corresponding to the objective vehicle device according to the predicted performance data and the device parameters; and
displaying the recommended calibration parameters to the user.

5. The vehicle calibrating method of claim 4, wherein determining the recommended calibration parameters corresponding to the objective vehicle device according to the predicted performance data and the device parameters comprises:
inputting the predicted performance data and the device parameters into a preset optimization model to obtain original calibration parameters, wherein the preset optimization model is trained according to preset multiple calibration parameter samples corresponding to the device parameters and a performance label corresponding to each of the multiple calibration parameter samples; and
verifying the original calibration parameters in a vehicle, and optimizing the original calibration parameters to obtain the recommended calibration parameters according to verification results of the original calibration parameters.

6. The vehicle calibrating method of claim 1, wherein displaying the predetermined driving scene to the user corresponding to the objective vehicle device in the preset VR environment comprises:
displaying multiple optional driving scenes in the preset VR environment, wherein the multiple optional driving scenes are generated by a virtual simulation on multiple optional real calibration scenes;
receiving selection information with respect to the multiple optional driving scenes;
determining the predetermined driving scene from the multiple optional driving scenes according to the selection information.

7. The vehicle calibrating method of claim 1, wherein after receiving the operation information of the objective vehicle device inputted by the user, the method further comprises:
adjusting the predetermined driving scene in the preset VR environment according to the operation information.

8. A vehicle calibrating device comprising:
at least one processor; and
a data storage storing one or more programs which when executed by the at least one processor, cause the at least one processor to:
display a predetermined driving scene corresponding to an objective vehicle device in a preset virtual reality (VR) environment, wherein the predetermined driving scene is generated by a virtual simulation of a real calibration scene corresponding to the objective vehicle device;
collect device parameters of the objective vehicle device in response to operation information of the objective vehicle device being received;
perform a simulation calculation to obtain predicted performance data of the objective vehicle device according to the operation information, the device parameters, and scene parameters of the predetermined driving scene; and
output the predicted performance data for calibrating the objective vehicle device.

9. The vehicle calibrating device of claim 8, wherein when the at least one processor performs the simulation calculation to obtain the predicted performance data of the objective vehicle device according to the operation information, the device parameters, and the scene parameters of the predetermined driving scene, the at least one processor is further caused to:
perform a respond data identification on the device parameters to determine whether the objective vehicle device outputs real response data with respect to the operation information; and
convert the real response data to obtain the predicted performance data according to a mapping relationship corresponding to the scene parameters when the objective vehicle device outputs the real response data;
wherein the mapping relationship is configured to indicate a mapping between the real response data and a performance of the objective vehicle device.

10. The vehicle calibrating device of claim 8, wherein when the at least one processor performs the simulation calculation to obtain the predicted performance data of the objective vehicle device according to the operation information, the device parameters, and the scene parameters of the predetermined driving scene, the at least one processor is further caused to:
determine a device type of the objective vehicle device according to the device parameters;
obtain simulation response data of the objective vehicle device by searching a response database corresponding to the device type according to the operation information and the scene parameters, wherein the response database comprises a plurality of simulation response data of the objective vehicle device corresponding to multiple optional operations in multiple optional scenes, and the response database is established according to at least one of historical calibration data of the objective vehicle equipment, a big data technology and, an artificial intelligence (AI) inference technology; and
determine the predicted performance data according to the simulation response data of the objective vehicle device.

11. The vehicle calibrating device of claim 8, wherein the at least one processor is further caused to:
determine recommended calibration parameters corresponding to the objective vehicle device according to the predicted performance data and the device parameters; and
display the recommended calibration parameters.

12. The vehicle calibrating device of claim 11, wherein when the at least one processor determines the recommended calibration parameters corresponding to the objective vehicle device according to the predicted performance data and the device parameters, the at least one processor is further caused to:
input the predicted performance data and the device parameters into a preset optimization model to obtain original calibration parameters, wherein the preset optimization model is trained according to preset multiple calibration parameter samples corresponding to the device parameters and a performance label corresponding to each of the multiple calibration parameter samples; and
verify the original calibration parameters in a vehicle, and optimize the original calibration parameters to obtain the recommended calibration parameters according to verification results of the original calibration parameters.

13. The vehicle calibrating device of claim 8, wherein when the at least one processor display the predetermined driving scene corresponding to the objective vehicle device in the preset VR environment, the at least one processor is further caused to:
display multiple optional driving scenes in the preset VR environment, wherein the multiple optional driving scenes are generated by a virtual simulation on multiple optional real calibration scenes;
receive selection information with respect to the multiple optional driving scenes;
determine the predetermined driving scene from the multiple optional driving scenes according to the selection information.

14. The vehicle calibrating device of claim 8, wherein the at least one processor is further caused to:
adjust the predetermined driving scene in the preset VR environment according to the operation information.

15. A non-transitory storage medium having stored thereon instructions that, when executed by a processor of a vehicle calibrating device, causes the vehicle calibrating device to perform a vehicle calibrating method, the vehicle calibrating method comprising:
displaying a predetermined driving scene corresponding to an objective vehicle device in a preset virtual reality (VR) environment, wherein the predetermined driving scene is generated by a virtual simulation of a real calibration scene corresponding to the objective vehicle device;
collecting device parameters of the objective vehicle device in response to operation information of the objective vehicle device being received;
performing a simulation calculation to obtain predicted performance data of the objective vehicle device according to the operation information, the device parameters, and scene parameters of the predetermined driving scene; and
outputting the predicted performance data for calibrating the objective vehicle device.
